(19) United States
(12) Patent Application Publication
(10) Pub. No.: US 2015/0318221 A1
(43) Pub. Date: Nov. 5, 2015

(54) METHOD AND APPARATUS FOR DETECTING FAULT IN THE SEMICONDUCTOR MENUFACTURING PROCESS AND RECORDING MEDIUM THEREOF

(71) Applicant: BISTel Inc., Seoul (KR)

(72) Inventors: Chang Ouk KIM, Seoul (KR); Chan Young PARK, Seoul (KR)

(73) Assignee: BISTel Inc., Seoul (KR)

(21) Appl. No.: 14/555,451

(22) Filed: Nov. 26, 2014

(30) Foreign Application Priority Data
May 2, 2014 (KR) 10-2014-0053625

(51) Int. Cl. H01L 21/66; G01B 5/04

(52) U.S. Cl. CPC H01L 22/12; G01B 5/043

(57) ABSTRACT

A method of detecting a fault in a semiconductor manufacturing process. The method includes obtaining measured data and reference data regarding at least one parameter related to semiconductor manufacturing conditions in a process included in a semiconductor manufacturing process during a pre-set period of time; converting the measured data and the reference data by using at least one principal component parameter obtained via principal component analysis with respect to the measured data and the reference data; calculating a similarity between the converted measured data and the converted reference data; and detecting a fault in the process based on the calculated similarity. As a result, production efficiency of a semiconductor manufacturing process may be improved.

### CROSS-REFERENCE TO RELATED APPLICATION

This application claims priority under 35 U.S.C. §119 to Korean Patent Application No. KR 10-2014-0053625, filed on May 2, 2014. The contents of this priority application are hereby incorporated by reference in their entirety.

### TECHNICAL FIELD

The invention relates to methods, devices and apparatus for detecting a fault in a semiconductor manufacturing process.

### BACKGROUND

Due to recent developments in sensor-related technologies and information technologies, it is now possible to monitor systems to be managed, e.g., semiconductor production facilities, stock markets, the Earth's atmosphere, etc., in real time. Characteristics of a monitoring system include collection of various parameters representing status of a corresponding system as chronological data and correlation between the chronological data.

In some cases, data values representing respective parameters are calculated as chronological data, and thus only one piece of chronological data is used per parameter. As a result, information regarding distribution of data per parameter may not be obtained, and thus structural characteristics regarding data are lost.

### SUMMARY

One aspect of the invention features a method of detecting a fault in a semiconductor manufacturing process. The method includes obtaining measured data and reference data regarding at least one parameter related to semiconductor manufacturing conditions in a process included in a semiconductor manufacturing process during a pre-set period of time; converting the measured data and the reference data by using at least one principal component parameter obtained via principal component analysis with respect to the measured data and the reference data; calculating a similarity between the converted measured data and the converted reference data; and detecting a fault in the process based on the calculated similarity. The method can detect possible faults in respective processes included in a semiconductor manufacturing process at improved precision by using the entire data measured in the respective processes. As a result, production efficiency of a semiconductor manufacturing process may be improved.

Another aspect of the invention features a fault detecting device for detecting a fault in a semiconductor manufacturing process, the fault detecting device includes an input unit, which obtains measured data and reference data regarding at least one parameter related to semiconductor manufacturing conditions in a process included in a semiconductor manufacturing process during a pre-set period of time; a control unit, which converts the measured data and the reference data by using at least one principal component parameter obtained via principal component analysis with respect to the measured data and the reference data and calculates a similarity between the converted measured data and the converted reference data; and a detection unit, which detects a fault in the process based on the calculated similarity.

Other aspects of the invention feature a computer-readable storage medium coupled to one or more processors and having instructions stored thereon which, when executed by the one or more processors, cause the one or more processors to perform operations in accordance with implementations of the method provided herein.

Other advantages of the invention will be appreciated from the description and the drawings. The features mentioned above and those set out below may also be used individually per se or together in any combination. The embodiments shown and described are not intended to be understood to be a conclusive listing but are instead of exemplary character for describing the invention.

### DESCRIPTION OF THE DRAWINGS

FIG. 1 is a schematic diagram of an example system for detecting a fault in a semiconductor manufacturing process.

FIG. 2 is a flowchart of an example method of detecting a fault in a semiconductor manufacturing process.

FIG. 3 is a schematic diagram showing a result of converting obtained measured data and obtained reference data based on principal components.

FIG. 4 is a flowchart of a method of calculating a similarity between converted measured data and converted reference data.

FIG. 5 is a schematic diagram showing a method that a fault detecting device calculates the first distance yardstick information between converted measured data and converted reference data.

FIG. 6 is a schematic diagram showing a method that a fault detecting device obtains second distance yardstick information between converted measured data and converted reference data.

FIG. 7 is a schematic diagram showing a method that a fault detecting device obtains third distance yardstick information between converted measured data and converted reference data.

FIG. 8 is a schematic block diagram of an example fault detecting device.

FIG. 9 is a schematic block diagram of another example fault detecting device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items.

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first,” “second,” etc., may be used to describe various components, such components must not be limited to the above terms. The above terms are used only to distinguish one component from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Embodiments of the present invention will be described below in more detail with reference to the accompanying drawings. Those components that are the same or are in correspondence are rendered the same reference numeral regardless of the figure number, and redundant explanations are omitted.

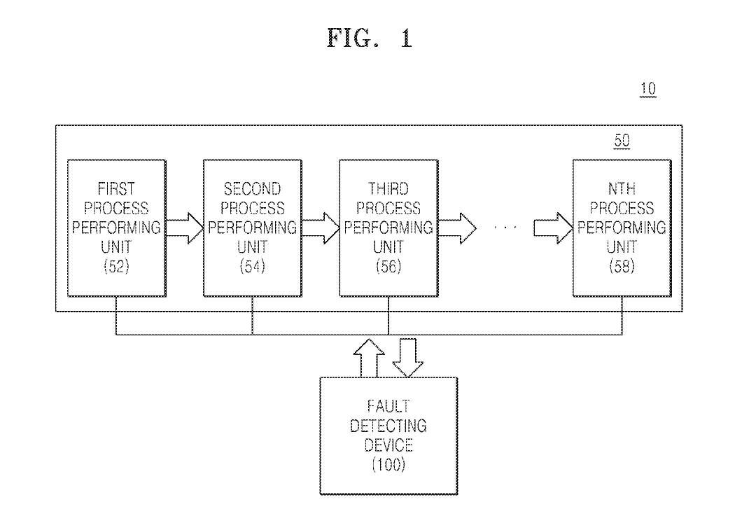

FIG. 1 is a diagram for describing a system 10 for detecting a fault in a semiconductor manufacturing process according to an embodiment of the present invention. In FIG. 1, only components of the system 10 for detecting a fault in a semiconductor manufacturing process related to the present embodiment are shown. Therefore, one of ordinary skill in the art will understand that the system 10 for detecting a fault in a semiconductor manufacturing process may further include other general-purpose components other than the components shown in FIG.

Referring to FIG. 1, the system 10 for detecting a fault in a semiconductor manufacturing process may include a semiconductor manufacturing device 50 and a fault detecting device for detecting faults in a semiconductor manufacturing process (100, referred to hereinafter as the ‘fault detecting device’).

The semiconductor manufacturing device 50 may perform a plurality of processes to manufacture a semiconductor. The plurality of processes may include wafer fabrication, circuit design, mask fabrication, wafer process, etc. Here, the wafer process may include processes, such as oxidization, photoresist application, exposure, development, etching, and ion implantation.

The semiconductor manufacturing device 50 shown in FIG. 1 may include a plurality of process performing units 52, 54, 56, and 58 capable of performing the wafer process. For example, the first process performing unit 52 may perform oxidization of a wafer, the second process performing unit 54 may perform photoresist application, and the third process performing unit 56 may perform exposure. Furthermore, the nth process performing unit 58 may perform ion implantation.

To produce a semiconductor product as intended by a user by using the semiconductor manufacturing device 50, respective process should be performed under preset conditions. Here, variables affecting performance and quality of semiconductor products manufactured in a semiconductor manufacturing process may be referred to as parameters. For example, in case of performing oxidization of a wafer at the first process performing unit 52, temperature, pressure, and process time for performing the oxidization process may be included in parameters. To produce a normal semiconductor product as intended by a user, temperature, pressure, and process time for performing a corresponding process at the first process performing unit 52 should be within preset ranges.

The fault detecting device 100 may monitor each of processes included in a semiconductor manufacturing process.

The fault detecting device 100 according to an embodiment of the present invention may compare measured data that is measured while a process is being performed to reference data. Here, the measured data may be data regarding at least one parameter, obtained during a preset period of time in a time section of performing a process. For example, measured data may include data regarding temperatures measured from a time point t1 to a time point t2 in a time section of performing a process. Reference data may be data regarding parameters in processes included in a process for manufacturing a normally manufactured semiconductor product. For example, reference data may include data regarding temperatures measured from a time point t1 to a time point t2 in a time section of performing a process for manufacturing a normally manufactured semiconductor product.

Meanwhile, the data regarding temperatures is merely an example, and measured data may be compared to reference data regarding all parameters affecting manufacturing of a semiconductor in processes, such as pressures.

The fault detecting device 100 compares measured data to reference data and may determine whether there is a fault in a process based on consistency between the measured data and the reference data. The fault detecting device 100 according to an embodiment of the present invention may determine whether there is a fault in a designated process more precisely by comparing measured data to reference data entirely instead of selecting portions of measured data obtained during a designated period of time and comparing the portions of the measured data to reference data.

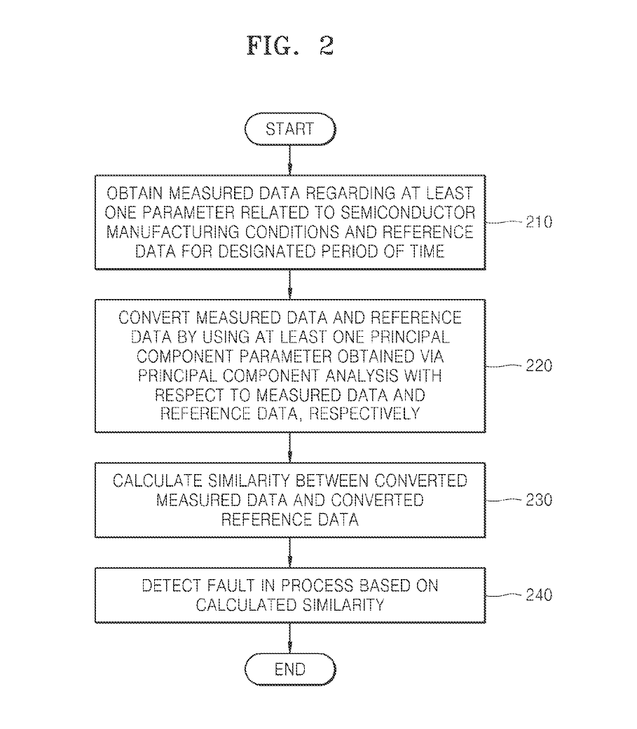

Hereinafter, referring to FIG. 2, a method that the fault detecting device 100 detects a fault in a semiconductor manufacturing process will be described. FIG. 2 is a flowchart for describing a method of detecting a fault in a semiconductor manufacturing process, according to an embodiment of the present invention.

In operation 210, the fault detecting device 100 obtains measured data and reference data regarding at least one parameter related to semiconductor manufacturing conditions during a preset period of time in a process included in a semiconductor manufacturing process.

As described above, parameters are variables affecting performance and quality of semiconductors manufactured in a semiconductor manufacturing process and may be related to semiconductor manufacturing conditions. For example, temperature and pressure for performing a process may be included in parameters.

Meanwhile, the fault detecting device 100 may obtain data regarding at least one parameter between a time point t1 and a time point t2 while a designated process is being performed. For example, the fault detecting device 100 may obtain measured data indicating 75 degrees, 78 degrees, 80 degrees, and 83 degrees between the time point t1 and the time point t2 as data regarding temperatures for performing a designated process.

Furthermore, the fault detecting device 100 may obtain reference data, which is data regarding a semiconductor manufacturing process in which a normally manufactured semiconductor product. The fault detecting device 100 may obtain temperature data regarding a normally manufactured semiconductor product for a time period a time point t1 to a time point t2 during which a designated process is performed, from reference data.

A designated process for manufacturing a semiconductor generally includes a plurality of parameters. If a plurality of parameters exists in a designated process, the fault detecting device 100 may refer to measured data and reference data for each of the plurality of parameters.

In operation 220, the fault detecting device 100 converts measured data and reference data based on at least one principal component parameter obtained by analyzing principal components regarding measured data and reference data, respectively.

The fault detecting device 100 according to an embodiment of the present invention may compare the entire data by analyzing principal components with respect to measured data and reference data, respectively. The principal components analysis is one of techniques for analyzing multi-variables and is a method for linearly converting data distributed along the original variable axis and indicating the converted data on a potential variable axis that is referred to as a principal component.

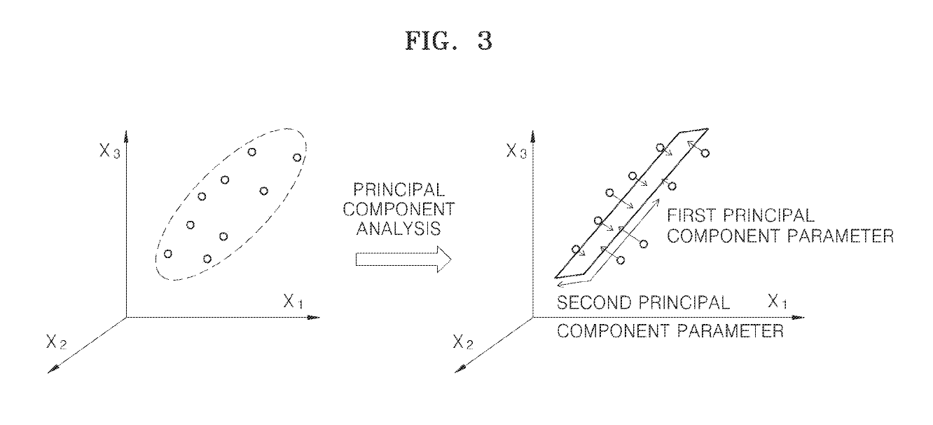

A method that the fault detecting device 100 performs a principal component analysis with respect to measured data and reference data will be described below in detail with reference to FIG. 3.

FIG. 3 is a diagram showing a result of converting obtained measured data and obtained reference data based on principal components, according to an embodiment of the present invention.

In case of performing a principal component analysis on a plurality of variables that are related to one another, a small number of new variables for securing as many information included in the plurality of variables as possible may be generated.

As described above, a plurality of parameters may exist in a designated process included in a semiconductor manufacturing process. For example, a temperature at which the designated process is performed, a pressure at which the designated process is performed, and volume of a gas introduced in the designated process may be included in the plurality of parameters.

The fault detecting device 100 may generate a smaller number of parameters including information regarding the plurality of parameters, e.g., a temperature, a pressure, and volume of a gas, via a principal component analysis.

Referring to FIG. 3, the left figure shows data regarding a temperature, a pressure, and a volume of a gas as the x1 axis, the x2 axis, and the x3 axis, respectively. The fault detecting device 100 may obtain a first principal component corresponding to the largest data dispersion direction, and a second principal component, which is a direction corresponding to the second largest data dispersion direction. A first principal component and a second principal component consist of combinations of data regarding each of three parameters.

The fault detecting device 100 may obtain a first principal component corresponding to the largest data dispersion direction and a second principal component corresponding to the second largest data dispersion direction via a principal component analysis with respect to three parameters (temperature, pressure, and volume of a gas). The first principal component and the second principal component are linear combinations of data with respect to each of the three parameters. Hereinafter, principal components obtained by the fault detecting device 100 via a principal component analysis with respect to parameters will be referred to as a principal component parameter. However, the present invention is not limited thereto, and three or more principal component parameters may be obtained based on a result of a principal component analysis.

Referring to the right figure of FIG. 3, measured data may be converted based on a first principal component parameter and a second principal component parameter obtained by the fault detecting device 100 as a result of performing a principal component analysis with respect to three parameters. Hereinafter, coordinate value of data converted by using a first principal component parameter and a second principal component parameter as principal component axis will be referred to as a score. A score may be generated as a result of a linear combination with data corresponding to parameters prior to conversion.

Meanwhile, a coefficient that data regarding parameters contributes to principal component parameters generated via a linear combination with the data regarding parameters may be referred to loading value. For example, if a loading value is large, it means that data regarding parameters significantly affects principal component parameters.

The fault detecting device 100 according to an embodiment of the present invention may perform a principal component analysis as described above with respect to not only measured data, but also reference data. The fault detecting device 100 may perform principal component analysis with respect to measured data and reference data and may obtain converted measured data and converted reference data. Here, the numbers of principal component parameters used for indicating the converted measured data and the converted reference data may be smaller than the number of parameters included in the respective data prior to conversion.

Referring back to FIG. 2, in operation 230, the fault detecting device 100 calculates a similarity between converted measured data and converted reference data.

The fault detecting device 100 may calculate first distance yardstick information, second distance yardstick information, and third distance yardstick information for calculating a similarity. Here, the first distance yardstick information is information based on an angle formed between a first principal component parameter of converted measured data and a first principal component parameter of converted reference data. The second distance yardstick information is information based on a ratio between distribution of converted measured data and distribution of converted reference data. In detail, the second distance yardstick information may be determined based on a ratio between an n^{th} eigenvalue of converted measured data and an n^{th} eigenvalue of converted reference data. Meanwhile, the third distance yardstick information is information based on a difference between the average of converted measured data and the average of converted reference data.

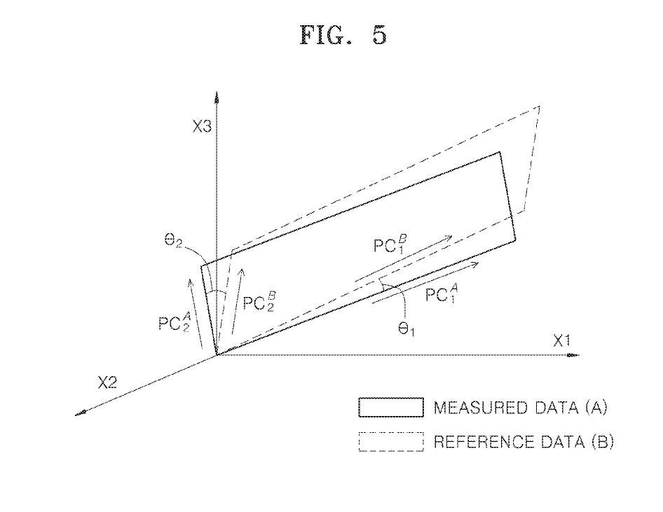

A method of calculating the plurality of distance yardstick information as described above will be described below in detail with reference to FIGS. 5 through 7.

In operation 240, the fault detecting device 100 detects a fault based on a calculated similarity.

The fault detecting device 100 determines whether a plurality of calculated distance yardstick information exceed pre-set critical values, respectively. For example, if one from among the first distance yardstick information, the second distance yardstick information, and the third distance yardstick information exceeds a preset corresponding critical value, the fault detecting device 100 may determine that a fault is detected in a designated process.

However, it is merely an example. According to another embodiment of the present invention, if all of a plurality of distance yardstick information respectively exceed pre-set critical values, the fault detecting device 100 may determine that a fault is detected in a designated process. The determination may be made based on characteristics of processes of a semiconductor manufacturing process or characteristics of a semiconductor product to manufacture.

The fault detecting device 100 may determine a critical value based on distances between components included in converted reference data and the median of the distances between the components. For example, the fault detecting device 100 may set a critical value by applying the Hampel's outlier detection model to distances between components included in converted reference data and the median of the distances between the components.

The Hampel's outlier detection model does not need supposition of data distribution and is capable of setting a critical value and predicting a fault regardless of an amount of data. In case of using the Hampel's outlier detection model, a fault may be predicted, even if first distance yardstick information, second distance yardstick information, and third distance yardstick information do not comply with a particular distribution. The fault detecting device 100 may set a critical value based on the Hampel's outlier detection model as described below.

First, the fault detecting device 100 may calculate distances di between components included in converted reference data and the median \tilde{d} of the distances between the components. Here, di may be an i^{th} distance between the components. The fault detecting device 100 may calculate a deviation rᵢ between the distances di between the components and the median \tilde{d}. The fault detecting device 100 may calculate the median |\tilde{r}ᵢ| of calculated values of |rᵢ|. Here, a first critical value T may be determined according to 4.5*|\tilde{r}ᵢ|. Meanwhile, a Hampel value ŕᵢ is the absolute value of a deviation between converted i^{th} measured data tᵢ and the median \tilde{t} of the converted measured data. In other words, a Hampel value ŕᵢ may be determined according to Equation 1 below:

ŕᵢ=|tᵢ−\tilde{t}| (1)

If a Hampel value ŕᵢ exceeds a first critical value T, the fault detecting device 100 may determine that a fault is detected in a designated process. Meanwhile, if a Hampel value ŕᵢ is smaller than or equal to the first critical value T, the fault detecting device 100 may determine that a designated process is normally performed.

The fault detecting device 100 sets critical values of respective distance yardstick information by calculating distances between converted measured data and converted reference data according to methods of calculating the respective distance yardstick information. Furthermore, the fault detecting device 100 may determine critical values with respect to the respective distance yardstick information based on the Hampel's outlier detection model.

If calculated first distance yardstick information exceeds a reference value determined based on the Hampel's outlier detection model with respect to the first distance yardstick information, the fault detecting device 100 may determine that a fault is detected in a corresponding process. Furthermore, if calculated second distance yardstick information exceeds a second critical value determined based on the Hampel's outlier detection model with respect to the second distance yardstick information, the fault detecting device 100 may determine that a fault is detected in a corresponding process. In the same regard, if calculated third distance yardstick information exceeds a third critical value determined based on the Hampel's outlier detection model with respect to the third distance yardstick information, the fault detecting device 100 may determine that a fault is detected in a corresponding process.

If a fault is detected in a process, the fault detecting device 100 according to an embodiment of the present invention may notify information regarding parameters included in the fault-detected process and information regarding a semiconductor manufacturing process included in the fault-detected process to a user.

Furthermore, if a fault is detected in a process, the fault detecting device 100 may stop performing the process. The fault detecting device 100 may stop a fault-detected process, thereby preventing possible waste of resources due to performance of a process next to the fault-detected process is performed.

Meanwhile, the determination of a critical value by the fault detecting device 100 based on the Hampel's outlier detection model is merely an example, and the present invention is not limited thereto. According to another embodiment of the present invention, the fault detecting device 100 may determine a critical value by applying the Grubb's test, the Chauvenet's criterion, the Peirce's criterion, or the generalized extreme studentized deviate (ESD) test.

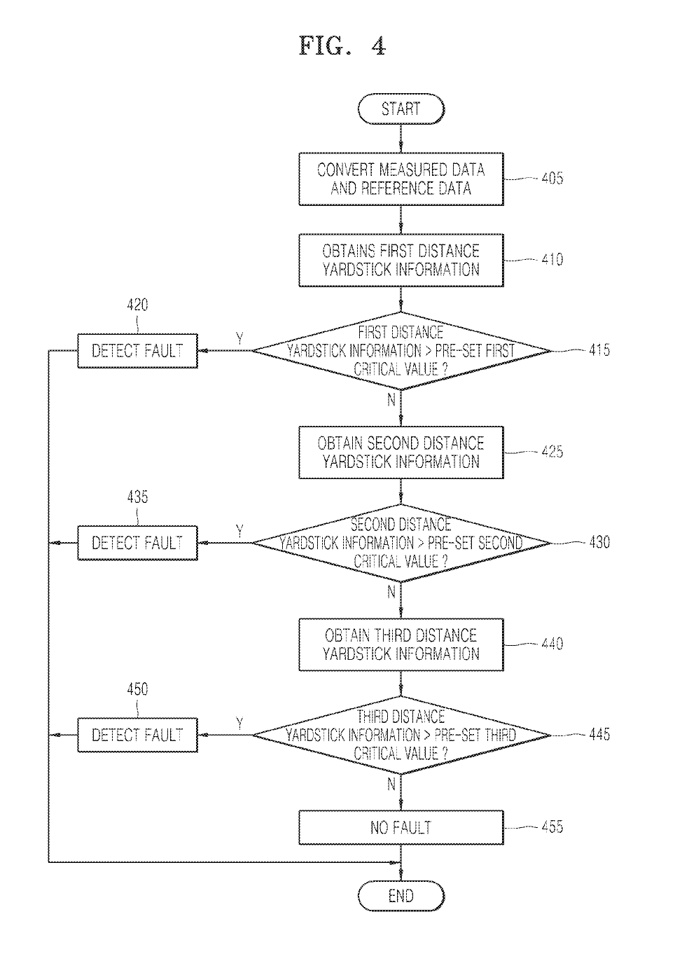

FIG. 4 is a flowchart for describing a method of calculating a similarity between converted measured data and converted reference data, according to an embodiment of the present invention.

In operation 405, the fault detecting device 100 converts measured data and reference data based on at least one principal component parameter obtained as a result of performing principal component analysis with respect to the measured data and the reference data. The fault detecting device 100 may obtain converted measured data and converted reference data for indicating pluralities of parameters included in measured data and reference data with smaller numbers of principal component parameters by performing principal component analysis with respect to the measured data and the reference data. Meanwhile, operation 405 shown in FIG. 4 may correspond to the operation 220 of FIG. 2.

In operation 410, the fault detecting device 100 obtains first distance yardstick information from converted measured data and converted reference data.

Hereinafter, a method that the fault detecting device 100 obtains the first distance yardstick information will be described in detail with reference to FIG. 5.

FIG. 5 is a diagram for describing a method that the fault detecting device 100 calculates the first distance yardstick information between converted measured data and converted reference data.

The fault detecting device 100 may obtain the first distance yardstick information by comparing angles between principal component parameters included in converted measured data and converted reference data.

In FIG. 5, converted measured data including two principal component parameters and converted reference data are 2-dimensionally illustrated. The converted measured data is indicated with the solid line, whereas the converted reference data is indicated with the dotted line.

In FIG. 5, θ₁ denotes an angle between the first principal component parameter PC₁^{A} of converted measured data and the first principal component parameter PC₁^{B} of converted reference data. Furthermore, θ₂ denotes an angle between the second principal component parameter PC₂^{A} of the converted measured data and the second principal component parameter PC₂^{B} of the converted reference data.

According to an embodiment of the present invention, first distance yardstick information is determined according to Equation 2 below:

$${D}_{1} = {\sum }_{i = 1}^{k} \vert cos {θ}_{i}^{2} - 1 \vert \qquad ( 2 )$$

Here, D₁ denotes first distance yardstick information and θᵢ denotes an angle between the i^{th} principal component parameter of converted measured data and the i^{th} principal component parameter of converted reference data. In the Equation 2, in terms of calculating distance yardstick information, the fault detecting device 100 may add −1 in the absolute value, thereby making the distance yardstick information zero when a viewing angle is 0 (cos θ₁ is 1). The closer the first distance yardstick information is to zero, the more similar measured data is determined by the fault detecting device 100 to be similar to reference data.

In operation 415, the fault detecting device 100 may determine whether first distance yardstick information exceeds a pre-set first critical value. Here, the first critical value may be determined as a result of applying the Hampel's outlier detection model to a method of calculating the first distance yardstick information. Description of the Hampel's outlier detection model is given above with reference to FIG. 3.

In operation 420, the fault detecting device 100 may determine that a fault is detected in a designated process. If first distance yardstick information exceeds a pre-set first critical value, the fault detecting device 100 may determine that a fault is detected in a designated process.

In operation 425, the fault detecting device 100 obtains second distance yardstick information from converted measured data and converted reference data.

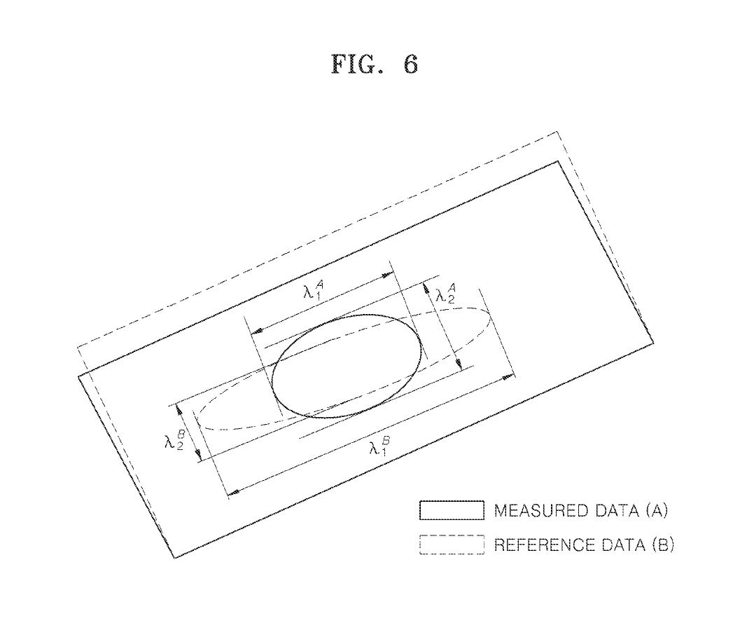

Hereinafter, a method that the fault detecting device 100 obtains second distance yardstick information will be described in detail with reference to FIG. 6.

FIG. 6 is a diagram for describing a method that the fault detecting device 100 obtains second distance yardstick information between converted measured data and converted reference data, according to an embodiment of the present invention.

Second distance yardstick information may be determined based on shape of a plane generated based on converted measured data and shape of a plane generated based on converted reference data. In the second distance yardstick information, a distance is determined based on eigenvalues of converted measured data and converted reference data.

Referring to FIG. 6, the ellipse indicated with the solid line is indicated with eigenvalues λ₁^{A} and λ₂^{A} of converted measured data, whereas the ellipse indicated with the dotted line is indicated with eigenvalues λ₁^{B} and λ₂^{B} of converted reference data.

According to an embodiment of the present invention, second distance yardstick information is determined according to Equation 3 below:

$${D}_{2} = {\sum }_{i = 1}^{k} \vert \frac{min ( {λ}_{i}^{A} , {λ}_{i}^{B} )}{max ( {λ}_{i}^{A} , {λ}_{i}^{B} )} - 1 \vert \qquad ( 3 )$$

Here, D₂ denotes second distance yardstick information, λ₁^{A} denotes the i^{th} eigenvalue of converted measured data, and λ₁^{B} denotes the i^{th} eigenvalue of converted reference data. The closer the second distance yardstick information is to zero, the more similar measured data is determined by the fault detecting device 100 to be similar to reference data.

In operation 435, the fault detecting device 100 may determine whether second distance yardstick information exceeds a pre-set second critical value. Here, the second critical value may be determined as a result of applying the Hampel's outlier detection model to a method of calculating the second distance yardstick information. Description of the Hampel's outlier detection model is given above with reference to FIG. 3.

In operation 435, the fault detecting device 100 may determine that a fault is detected in a designated process. If second distance yardstick information exceeds a pre-set second critical value, the fault detecting device 100 may determine that a fault is detected in a designated process.

In an operation 440, the fault detecting device 100 obtains third distance yardstick information from converted measured data and converted reference data.

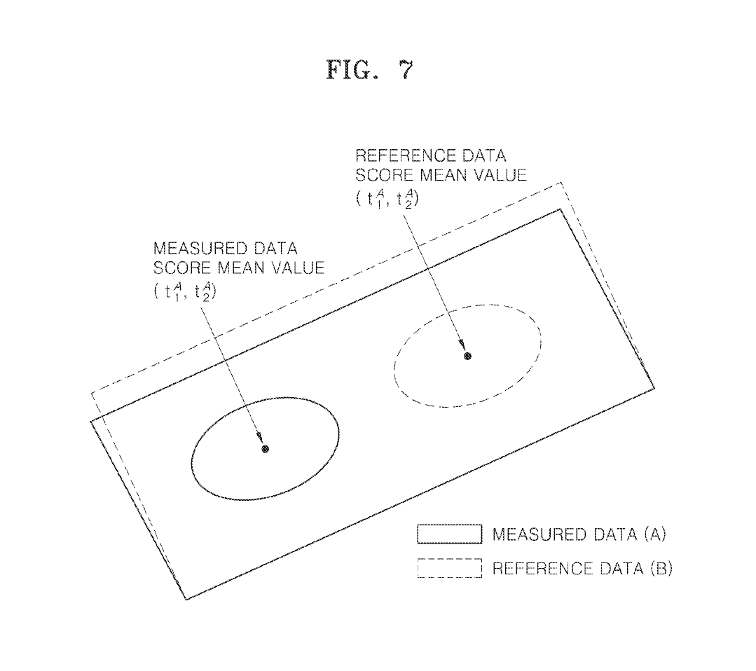

Hereinafter, a method that the fault detecting device 100 obtains third distance yardstick information will be described in detail with reference to FIG. 7.

FIG. 7 is a diagram for describing a method that the fault detecting device 100 obtains third distance yardstick information between converted measured data and converted reference data, according to an embodiment of the present invention.

Third distance yardstick information may be calculated based on a location difference between a plane generated based on converted measured data and a plane generated based on converted reference data.

In FIG. 7, the plane that is generated based on converted measured data and indicated with the solid line and the plane that is generated based on converted reference data and indicated with the dotted line feature distribution locations. To compare distribution locations of the respective planes, the fault detecting device 100 calculates the average of converted measured data and the average of converted reference data. For example, if the average of converted measured data is (t₁^{A}, t₂^{A}) and the average of converted reference data is (t₁^{B}, t₂^{B}), a distance between the two averages may be third distance yardstick information.

Third distance yardstick information is determined according to Equation 4 below:

$${D}_{3} = \sqrt{{\sum }_{i = 1}^{k} {( {t}_{i}^{A} - {t}_{i}^{B} )}^{2}} \qquad ( 4 )$$

The closer the third distance yardstick information D₃ is to zero, the more similar measured data is determined by the fault detecting device 100 to be similar to reference data.

In operation 445, the fault detecting device 100 may determine whether third distance yardstick information exceeds a pre-set third critical value. Here, the third critical value may be determined as a result of applying the Hampel's outlier detection model to a method of calculating the third distance yardstick information. Description of the Hampel's outlier detection model is given above with reference to FIG. 3.

In operation 450, the fault detecting device 100 may determine that a fault is detected in a designated process. If third distance yardstick information exceeds a pre-set third critical value, the fault detecting device 100 may determine that a fault is detected in a designated process.

In operation 455, the fault detecting device 100 may determine that no fault is detected in a process. If first distance yardstick information, second distance yardstick information, and third distance yardstick information do not respectively exceed a pre-set first critical value, a pre-set second critical value, and a pre-set third critical value, the fault detecting device 100 may determine that no fault is detected in a process.

However, it is merely an example. According to another embodiment of the present invention, if all of a plurality of distance yardstick information respectively exceed pre-set critical values, the fault detecting device 100 may determine that a fault is detected in a process. The determination may be made based on characteristics of processes of a semiconductor manufacturing process or characteristics of a semiconductor product to manufacture, according to the present application.

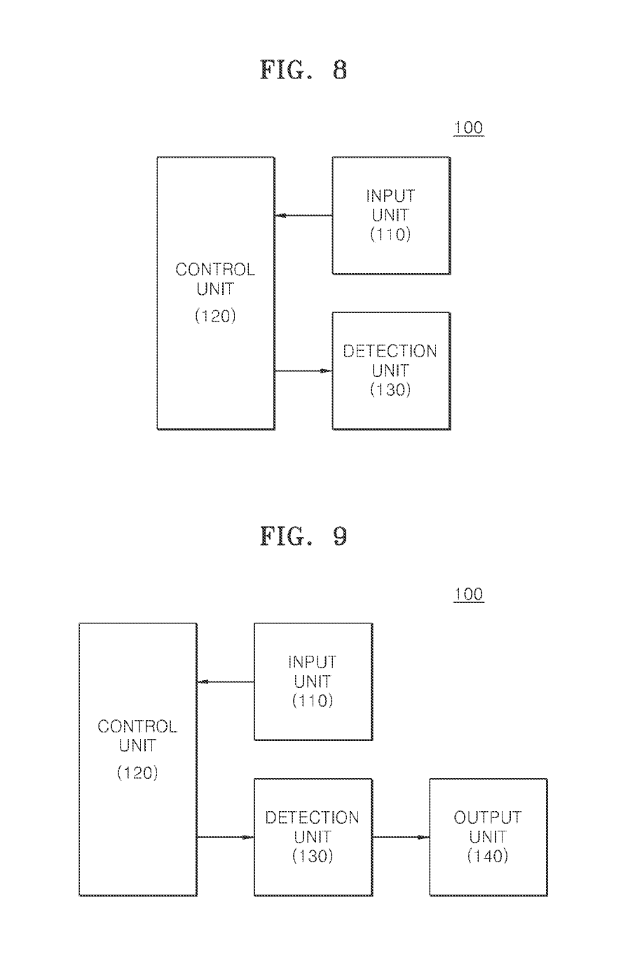

FIGS. 8 and 9 are block diagrams for describing the fault detecting device 100 according to an embodiment of the present invention.

As shown in FIG. 8, the fault detecting device 100 may include an input unit 110, a control unit 120, and a detection unit 130. However, not all of the components shown in FIG. 8 are essential components. The fault detecting device 100 may be embodied with components more than or less than the components shown in FIG. 8.

For example, the fault detecting device 100 may include not only the input unit 110, the control unit 120, and the detection unit 130, but also an output unit 140. Detailed descriptions of the above-stated components will be given below.

The input unit 110 obtains measured data and reference data regarding at least one parameter related to semiconductor manufacturing conditions in a process included in a semiconductor manufacturing process during a pre-set period of time.

As described above, parameters are variables affecting performance and quality of semiconductors manufactured in a semiconductor manufacturing process and may be related to semiconductor manufacturing conditions. For example, temperature and pressure for performing a designated process may be included in parameters.

Meanwhile, the input unit 110 may obtain data regarding at least one parameter during a time period between a time point t1 and a time point t2, in which a process is being performed. For example, the fault detecting device 100 may obtain data regarding a temperature at which a process is performed between the time point t1 and the time point t2.

Furthermore, the input unit 110 may obtain reference data, which is data regarding a manufacturing process corresponding to a normally produced semiconductor product. For example, the input unit 110 may obtain temperature data regarding a normally manufactured semiconductor product during a time period between the time point t1 and the time point t2, in which a process is being performed, from reference data.

A designated process for manufacturing a semiconductor generally includes a plurality of parameters. If plurality of parameters exists in a designated process, the input unit 110 may refer to measured data and reference data for each of the plurality of parameters.

The control unit 120 converts measured data and reference data based on at least one principal component parameter obtained by analyzing principal components regarding measured data and reference data, respectively. The control unit 120 may compare the entire data by analyzing principal components with respect to measured data and reference data, respectively. Here, the numbers of principal component parameters used for indicating the converted measured data and the converted reference data may be smaller than the number of parameters included in the respective data prior to conversion.

Meanwhile, the control unit 120 calculates a similarity between converted measured data and converted reference data.

The control unit 120 according to an embodiment of the present invention may calculate first distance yardstick information, second distance yardstick information, and third distance yardstick information for calculating a similarity. Here, the first distance yardstick information is information based on an angle formed between a first principal component parameter of converted measured data and a first principal component parameter of converted reference data. The second distance yardstick information is information based on a ratio between distribution of converted measured data and distribution of converted reference data. In detail, the second distance yardstick information may be determined based on a ratio between an n^{th} eigenvalue of converted measured data and an n^{th} eigenvalue of converted reference data. Meanwhile, the third distance yardstick information is information based on a difference between the average of converted measured data and the average of converted reference data.

The detection unit 130 determines whether there is a fault in a process based on results of the calculations.

The detection unit 130 determine whether a plurality of calculated distance yardstick information exceed pre-set critical values, respectively. For example, if one from among the first distance yardstick information, the second distance yardstick information, and the third distance yardstick information exceeds a preset corresponding critical value, the detection unit 130 may determine that a fault is detected in a designated process.

However, it is merely an example. According to another embodiment of the present invention, the detection unit 130, if all of a plurality of distance yardstick information respectively exceed pre-set critical values, the detection unit 130 may determine that a fault is detected in a process. The determination may be made based on characteristics of processes of a semiconductor manufacturing process or characteristics of a semiconductor product to manufacture, according to the present application.

The detection unit 130 according to an embodiment of the present invention may determine a critical value based on distances between components included in converted reference data and the median of the distances between the components. For example, the detection unit 130 may set a critical value by applying the Hampel's outlier detection model to distances between components included in converted reference data and the median of the distances between the components.

If a fault is detected in a process, the output unit 140 may notify information regarding parameters included in the fault-detected process and information regarding a semiconductor manufacturing process included in the fault-detected process to a user.

Furthermore, if the detection unit 130 detects a fault in a process, the output unit 140 may transmit a control signal for stopping performance of a process to a semiconductor manufacturing device (50, FIG. 1). A control signal transmitted by the output unit 140 stops performance of a process, thereby preventing possible waste of resources due to performance of a process next to the fault-detected process is performed.

The device described herein may comprise a processor, a memory for storing program data and executing it, a permanent storage such as a disk drive, a communications port for handling communications with external devices, and user interface devices, including a display, keys, etc. When software modules are involved, these software modules may be stored as program instructions or computer readable codes executable on the processor on a computer-readable media such as read-only memory (ROM), random-access memory (RAM), CD-ROMs, magnetic tapes, floppy disks, and optical data storage devices. The computer readable recording medium can also be distributed over network coupled computer systems so that the computer readable code is stored and executed in a distributed fashion. This media can be read by the computer, stored in the memory, and executed by the processor.

As described above, in a method of detecting a fault in a semiconductor manufacturing process according to the one or more of the above embodiments of the present invention, the entire data obtained in the semiconductor manufacturing process is compared to the entire reference data, and thus occurrence of a fault in the semiconductor manufacturing process may be detected more precisely.

The device described herein may comprise a processor, a memory for storing program data and executing it, a permanent storage such as a disk drive, a communications port for handling communications with external devices, and user interface devices, including a display, keys, etc. When software modules are involved, these software modules may be stored as program instructions or computer readable codes executable on the processor on a computer-readable media such as read-only memory (ROM), random-access memory (RAM), CD-ROMs, magnetic tapes, floppy disks, and optical data storage devices. The computer readable recording medium can also be distributed over network coupled computer systems so that the computer readable code is stored and executed in a distributed fashion. This media can be read by the computer, stored in the memory, and executed by the processor.

For the purposes of promoting an understanding of the principles of the invention, reference has been made to the preferred embodiments illustrated in the drawings, and specific language has been used to describe these embodiments. However, no limitation of the scope of the invention is intended by this specific language, and the invention should be construed to encompass all embodiments that would normally occur to one of ordinary skill in the art.

The present invention may be described in terms of functional block components and various processing steps. Such functional blocks may be realized by any number of hardware and/or software components configured to perform the specified functions. For example, the present invention may employ various integrated circuit components, e.g., memory elements, processing elements, logic elements, look-up tables, and the like, which may carry out a variety of functions under the control of one or more microprocessors or other control devices. Similarly, where the elements of the present invention are implemented using software programming or software elements the invention may be implemented with any programming or scripting language such as C, C++, Java, assembler, or the like, with the various algorithms being implemented with any combination of data structures, objects, processes, routines or other programming elements. Functional aspects may be implemented in algorithms that execute on one or more processors. Furthermore, the present invention could employ any number of conventional techniques for electronics configuration, signal processing and/or control, data processing and the like. The words “mechanism” and “element” are used broadly and are not limited to mechanical or physical embodiments, but can include software routines in conjunction with processors, etc.

The particular implementations shown and described herein are illustrative examples of the invention and are not intended to otherwise limit the scope of the invention in any way. For the sake of brevity, conventional electronics, control systems, software development and other functional aspects of the systems (and components of the individual operating components of the systems) may not be described in detail. Furthermore, the connecting lines, or connectors shown in the various figures presented are intended to represent exemplary functional relationships and/or physical or logical couplings between the various elements. It should be noted that many alternative or additional functional relationships, physical connections or logical connections may be present in a practical device. Moreover, no item or component is essential to the practice of the invention unless the element is specifically described as “essential” or “critical”.

The use of the terms “a” and “an” and “the” and similar referents in the context of describing the invention (especially in the context of the following claims) are to be construed to cover both the singular and the plural. Furthermore, recitation of ranges of values herein are merely intended to serve as a shorthand method of referring individually to each separate value falling within the range, unless otherwise indicated herein, and each separate value is incorporated into the specification as if it were individually recited herein. Finally, the steps of all methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. Numerous modifications and adaptations will be readily apparent to those skilled in this art without departing from the spirit and scope of the present invention.

What is claimed is:

1. A method of detecting a fault in a semiconductor manufacturing process, the method comprising:
obtaining measured data and reference data regarding at least one parameter related to semiconductor manufacturing conditions in a process included in a semiconductor manufacturing process during a pre-set period of time;
converting the measured data and the reference data by using at least one principal component parameter obtained via principal component analysis with respect to the measured data and the reference data;
calculating a similarity between the converted measured data and the converted reference data; and
detecting a fault in the process based on the calculated similarity.

2. The method of claim 1, wherein the calculating of the similarity comprises obtaining at least one from among first distance yardstick information, second distance yardstick information, and third distance yardstick information between the converted measured data and the converted reference data,
the first distance yardstick information is information based on an angle formed between a first principal component parameter of the converted measured data and a first principal component parameter of the converted reference data,
the second distance yardstick information is information based on a ratio between distribution of the converted measured data and distribution of the converted reference data, and
the third distance yardstick information is information based on a difference between the average of the converted measured data and the average of the converted reference data.

3. The method of claim 2, wherein the second distance yardstick information is determined based on a ratio between an n^{th} eigenvalue of the converted measured data and an n^{th} eigenvalue of the converted reference data.

4. The method of claim 2, wherein the detecting of the fault comprises:
determining whether the first distance yardstick information, the second distance yardstick information, and the third distance yardstick information exceed first through third critical values, respectively; and,
if at least one from among the first through third distance yardstick information exceeds the corresponding critical value, determining that there is a fault in the designated process.

5. The method of claim 4, wherein the first through third critical values are determined based on distances between components included in the converted reference data and the median of the distances between the components.

6. The method of claim 5, wherein the first through third critical values are determined by applying the Hampel's outlier detection model to distances between components included in the converted reference data and the median of the distances between the components.

7. The method of claim 1, further comprising, if a fault is detected in a process, notifying information regarding parameters included in the fault-detected process and information regarding a semiconductor manufacturing process included in the fault-detected process to a user.

8. A fault detecting device for detecting a fault in a semiconductor manufacturing process, the fault detecting device comprising:
an input unit, which obtains measured data and reference data regarding at least one parameter related to semiconductor manufacturing conditions in a process included in a semiconductor manufacturing process during a pre-set period of time;
a control unit, which converts the measured data and the reference data by using at least one principal component parameter obtained via principal component analysis with respect to the measured data and the reference data and calculates a similarity between the converted measured data and the converted reference data; and
a detection unit, which detects a fault in the process based on the calculated similarity.

9. The fault detecting device of claim 8, wherein the control unit obtains at least one from among first distance yardstick information, second distance yardstick information, and third distance yardstick information between the converted measured data and the converted reference data,
the first distance yardstick information is information based on an angle formed between a first principal component parameter of the converted measured data and a first principal component parameter of the converted reference data,
the second distance yardstick information is information based on a ratio between distribution of the converted measured data and distribution of the converted reference data, and
the third distance yardstick information is information based on a difference between the average of the converted measured data and the average of the converted reference data.

10. The fault detecting device of claim 9, wherein the second distance yardstick information is determined based on a ratio between an n^{th} eigenvalue of the converted measured data and an n^{th} eigenvalue of the converted reference data.

11. The fault detecting device of claim 9, wherein the detection unit determines whether the first distance yardstick information, the second distance yardstick information, and the third distance yardstick information exceed first through third critical values, respectively; and,
if at least one from among the first through third distance yardstick information exceeds the corresponding critical value, the detection unit determines that there is a fault in the designated process.

12. The fault detecting device of claim 11, wherein the first through third critical values are determined based on distances between components included in the converted reference data and the median of the distances between the components.

13. The fault detecting device of claim 12, wherein the first through third critical values are determined by applying the Hampel's outlier detection model to distances between components included in the converted reference data and the median of the distances between the components.

14. The fault detecting device of claim 8, further comprising an output unit, which, if a fault is detected in a process, notifies information regarding parameters included in the fault-detected process and information regarding a semiconductor manufacturing process included in the fault-detected process to a user.

15. A computer readable recording medium having recorded thereon a computer program for implementing the method of claim 1.
